(19) United States
(12) Patent Application Publication
(10) Pub. No.: US 2006/0108146 A1
(43) Pub. Date: May 25, 2006

(54) Structure of electronic package and method for fabricating the same

(75) Inventors: Enboa Wu, Taipei City (TW); Shou-Lung Chen, Taoyuan County (TW)

Correspondence Address: THE WEBB LAW FIRM, P.C., 700 KOPPERS BUILDING, 436 SEVENTH AVENUE, PITTSBURGH, PA, 15219, US

(73) Assignee: INDUSTRIAL TECHNOLOGY RESEARCH INSTITUTE, Hsinchu (TW)

(21) Appl. No.: 11/247,506

(22) Filed: Oct. 11, 2005

(30) Foreign Application Priority Data
Nov. 19, 2004 (TW) 93135698

(51) Int. Cl. H05K 1/16

(52) U.S. Cl. 174/260

(57) ABSTRACT

A structure of an electronic package and a method for fabricating the structure are provided in the present invention. The provided method includes steps of providing a first substrate, forming an electronic component thereon, providing a second substrate to cover the first substrate and the electronic component so that a sandwich structure is formed thereby, providing a lamination process for the sandwich structure so that the electronic component is embedded therein, forming plural vias which are located at the I/O pad of the electronic component and penetrate the second substrate for connecting thereto, filling the vias with a conductive material, and patterning the sandwich structure. Hence the structure of an electronic package is fabricated thereby.

### FIELD OF THE INVENTION

The present invention relates to an electronic package structure and a method for fabricating the electronic package structure, and more particularly, to a miniaturized electronic package structure and a method for fabricating it.

### BACKGROUND OF THE INVENTION

For the trend toward the miniaturization for the electronic device, the electronic manufacturers involved in the technology have made more and more efforts in manufacturing a portable and miniature electronic device with a great functionality and operation density. Since an electrical connection between the circuit in the package structure for an electronic device and the integrated circuit (IC) chip applied therein must be well made for being operated with a high efficiency, an increasing development is also necessary for the electronic package technology to provide a package structure having the improved functionalities of electricity conducting, signal transferring, thermal dissipating and circuitry protecting.

There are three typical techniques for fabricating the package structure electrically connected to the IC chip, including the wire bonding technique, the tape automated bonding (TAB) technique, and the flip chip (FC) technique.

The processes for the wire bonding technique, which had been completely developed in early days, are illustrated as follows. First, a die is well fixed on the lead frame or carriers made by other materials. Then, fine metal wires are used to connect the circuitry on the die with the pins on the lead frame via the thermal compression process or/and the ultrasonic bonding process. Such a bonding technique has a much simple and convenient process, and the relevant techniques and apparatuses are also well developed. However, the wiring bonding technique has some limitations in providing a miniaturized IC chip with a good performance although it is still popularized for its simple and convenient process in this art.

The TAB technique is initially provided by GE corp. in 1960s. In the process for TAB, the die is attached to the metallic circuitry on the tape. The tape is made of polyimide and the metallic circuitry thereon is commonly fabricated by the copper foil. The inner pins of the die are attached and connected to the bumps via the thermal compression process. The TAB technique is advantageous for providing a chip with a reduced pitch and thickness, and hence the provided chip will has a larger amount of I/O terminals thereon. The TAB technique is useful for providing a miniaturized IC device, however, the package density thereof still needs to be improved and the drawback of the complicated fabrication for the bump is also necessary to be overcome.

The FC technique is expected as a principle fabrication process for the package structure. First, plural solder bumps are formed on the metal pad having dies thereon. On the other hand, plural joints corresponding to the solder bumps are also formed on a provided substrate. The metal pad is then turned over, so that the solder bumps thereon are respectively targeted at the joints. A step of reflowing is performed, so that all of the solder bumps are respectively bonded to the corresponding joints at the same time, and the desired package structure is fabricated.

The package structure fabricated by the FC technique has a shorter connection length, a better electrical performance and a higher I/O terminal density. Such a technique has a great potential in application since it not only meets the demand for the device miniaturization, but also improves the yield of the wafer fabrication. In order to provide a good package structure, the surface tension of the melted solder bumps and the collapse height thereof need to be precisely controlled for supporting the chip, and hence a great effort is still necessary therefor.

As to the electronic device fabrication, there are a lot of developments focused on the built-in capacitance substrate for simplifying the complicated process involved in the fabrication. Such a component built-in module and the method for fabricating the same are disclosed in U.S. Pat. No. 6,489,685. Please refer to FIG. 1, which is a cross-section view for schematically illustrating the module. The component built-in module 1 includes an electric insulation layer 101, traces 102a and 102b, and the inner via 104, wherein the electric insulation layer 101 is made of epoxy. The electronic component 103 is embedded on the electric insulation layer 101 by FC bonding and further embedded on each of the traces 102a and 102b through the solder bumps 105.

As a result, the height of the component built-in module 1 and the length of the inner via therein are reduced. The disclosed method provides a component built-in module with a high packaging density and a reliable connection. However, the use of the solder bumps 105 is still necessary in the method. The solder bumps significantly decrease the maximal working frequency of the module, so that the electrical performance thereof would be inversely affected.

Based on the above, it is apparent that an improved structure of the electronic package and an improved fabrication therefor are necessary for the miniaturized electronic device having a good performance in the rapidly developed IC technology. In order to overcome the drawbacks of the conventional techniques as mentioned, a structure of the electronic package and a method for fabricating the same are provided in the present invention. The method of the present invention relates to a bumpless process for an organic substrate. When the substrate is fabricated, the electronic component thereon is also wired and packaged at the same time. It is advantageous that the present invention provides a simplified process and the package structure having a greater performance than the conventional ones.

### SUMMARY OF THE INVENTION

In accordance with a first aspect of the present invention, an electronic package structure is provided. The electronic package structure includes a first substrate having a first upper surface and a first lower surface, a second substrate having a second upper surface and a second lower surface, at least an electronic component located between the first lower surface and the second upper surface, a plurality of vias passing through the second substrate and connected to the electronic component, and a patterning layer located at least on one of the first upper surface and the second lower surface.

In accordance with a second aspect of the present invention, an electronic package structure is provided. The electronic package structure includes a first substrate and a second substrate, at least a third substrate located between the first substrate and the second substrate, at least two electronic components respectively located between the first substrate and the third substrate and between the second substrate and the third substrate to form at least a sandwich structure, a plurality of vias passing through the first substrate and the second substrate and connected to the electronic components located therebetween, and a patterning layer located on an outer surface of the sandwich structure.

Preferably, the electronic component is embedded between the first lower surface and the second upper surface by performing a lamination process on the first substrate and the second substrate, and the electronic package structure is patterned and wired via the patterning layer.

Preferably, the first substrate is one selected from a group consisting of a resin coated copper-foil substrate, an ajinomoto build-up film substrate and a flexible substrate.

Preferably, the second substrate and the first substrate are made of the same material.

Preferably, the first substrate further includes at least a fillister thereon.

Preferably, the fillister is pre-formed on the first substrate.

Preferably, the electronic component is located on a position corresponding to the fillister.

Preferably, the electronic component is one of an active electronic component and a passive electronic component.

Preferably, the active component is one selected from a group consisting of a die, a semiconductor, a transistor, and an integrated circuit.

Preferably, the passive electronic component further includes one of a discrete passive electronic component and a built-in passive electronic component.

Preferably, the discrete passive electronic component is one selected from a group consisting of a capacitor, a resistor and an inductor.

Preferably, the built-in passive electronic component is made of one selected from a group consisting of a capacitance material, a resistance material and an inductance material.

Preferably, the resistance material is fabricated on the first substrate by a stencil printing process.

Preferably, the electronic package structure further includes plural balls on the patterning layer.

In accordance with a third aspect of the present invention, a method for fabricating an electronic package structure is provided. The method includes steps of (a) providing a first substrate, (b) forming an electronic component on the first substrate, (c) providing a second substrate on the electronic component, so that the first substrate and the electronic component are covered therewith and a sandwich structure is formed thereby, (d) performing a lamination process on the sandwich structure, so that the electronic component is embedded therein, (e) forming a plurality of vias on the sandwich structure, (f) filling the plurality of vias with a conductive material, and (g) patterning the sandwich structure.

Preferably, the second substrate is provided on the electronic component by a build-up process in the step (c).

Preferably, the plurality of vias are formed by one selected from a group consisting of a UV laser, a gas laser and a chemical etching in the step (e).

Preferably, after the step (g), the method further includes a step of (h) performing a solder mask process on the sandwich structure.

Preferably, after the step (g), the method further includes a step of (h′) performing a ball-mounting process on the sandwich structure.

Preferably, the method further includes a step of (i) singulating the sandwich structure into the electronic package structure.

Preferably, after the step (g), the method further includes a step of (h″) singulating the sandwich structure into the electronic package structure.

Preferably, the first substrate is one selected from a group consisting of a resin coated copper-foil substrate, an ajinomoto build-up film substrate and a flexible substrate.

Preferably, the second substrate and the first substrate are made of the same material.

Preferably, the first substrate further includes at least a fillister thereon.

Preferably, the fillister is pre-formed on the first substrate.

Preferably, the electronic component is located on a position corresponding to the fillister.

Preferably, the electronic component is one of an active electronic component and a passive electronic component.

Preferably, the active component is one selected from a group consisting of a die, a semiconductor, a transistor and an integrated circuit.

Preferably, the passive electronic component further includes one of a discrete passive electronic component and a built-in passive electronic component.

Preferably, the discrete passive electronic component is one selected from a group consisting of a capacitor, a resistor and an inductor.

Preferably, the built-in passive electronic component is one selected from a group consisting of a capacitance material, a resistance material and an inductance material.

Preferably, the resistance material is fabricated on the first substrate by a stencil printing process.

The foregoing and other features and advantages of the present invention will be more clearly understood through the following descriptions with reference to the drawings, wherein:

### BRIEF DESCRIPTION OF THE DRAWINGS

FIG. 1 is a diagram illustrating a conventional package structure according to the prior art;

FIGS. 2(a) to 2(h) are diagrams schematically illustrating the method according to a preferred embodiment of the present invention;

FIGS. 3(a) and 3(b) are diagrams illustrating the substrates suitable for the package structure of the present invention;

FIG. 4(a) is a diagram illustrating a 2D package structure according to a first preferred embodiment of the present invention;

FIG. 4(b) is a diagram illustrating a 3D package structure according to the first preferred embodiment of the present invention;

FIG. 5 is a diagram illustrating the package structure according to a second preferred embodiment of the present invention; and

FIG. 6 is a diagram illustrating the package structure according to a third preferred embodiment of the present invention.

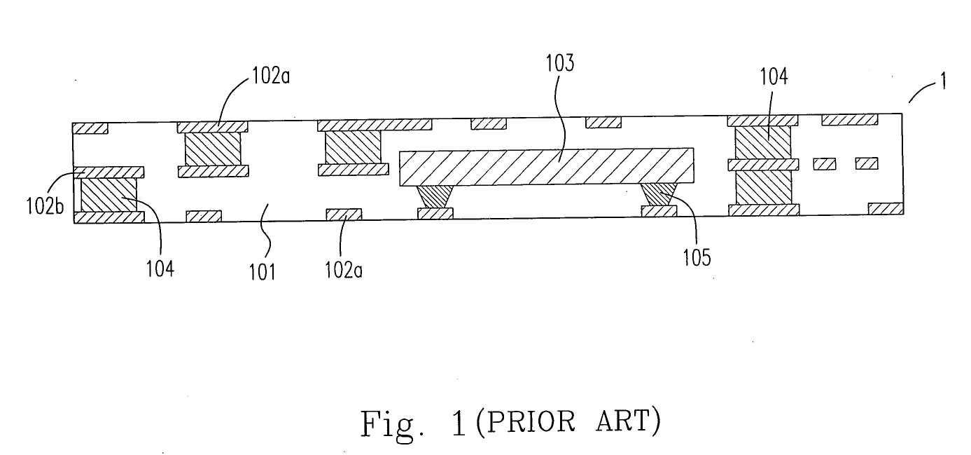

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

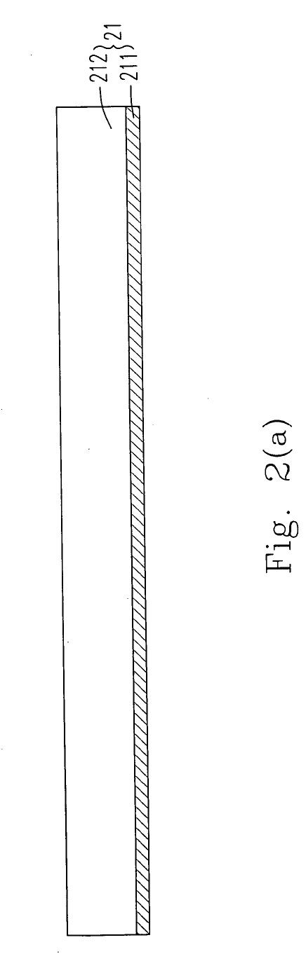

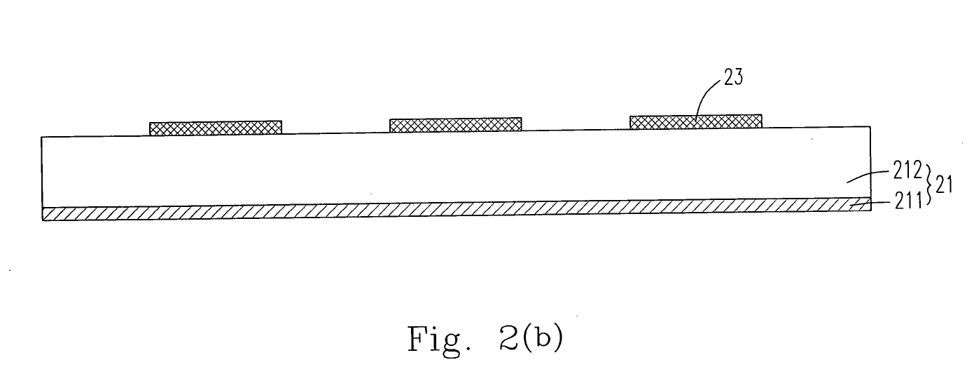

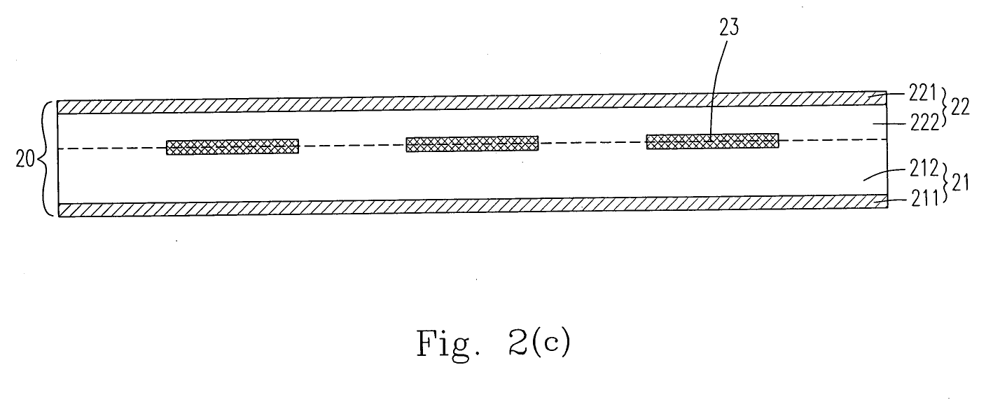

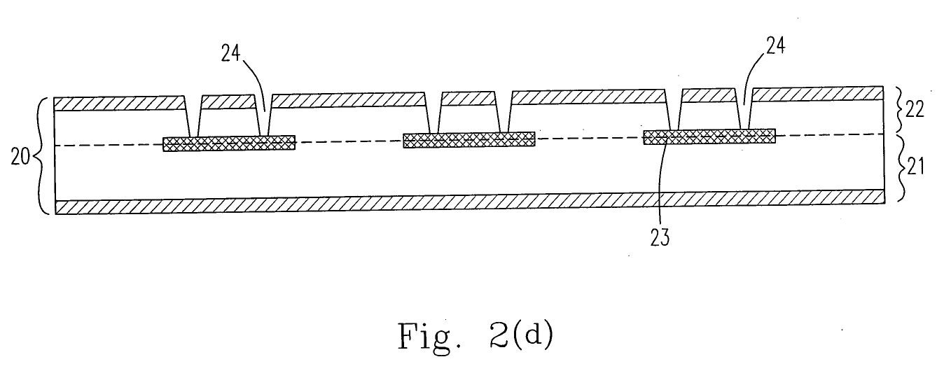

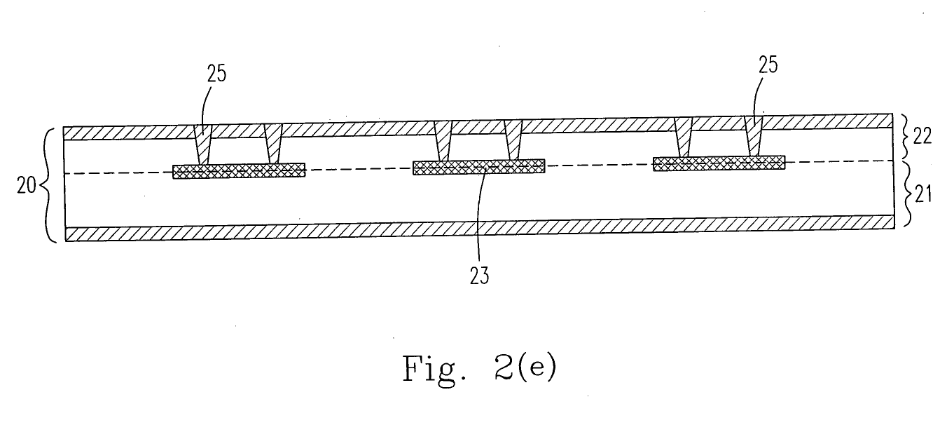

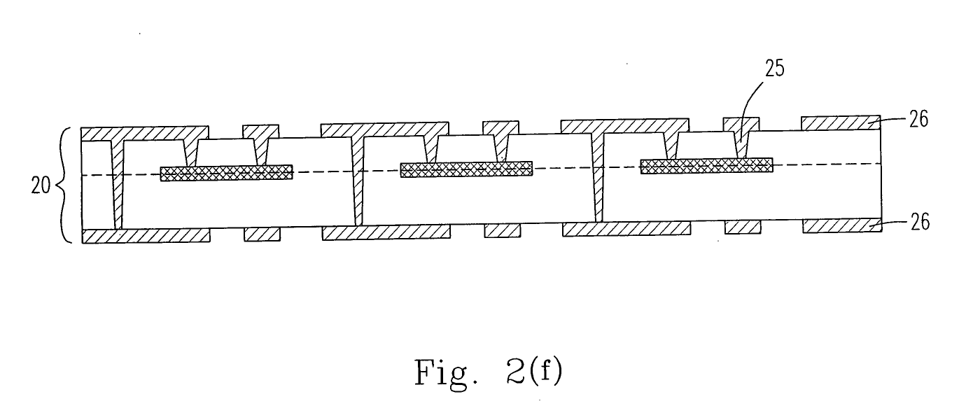

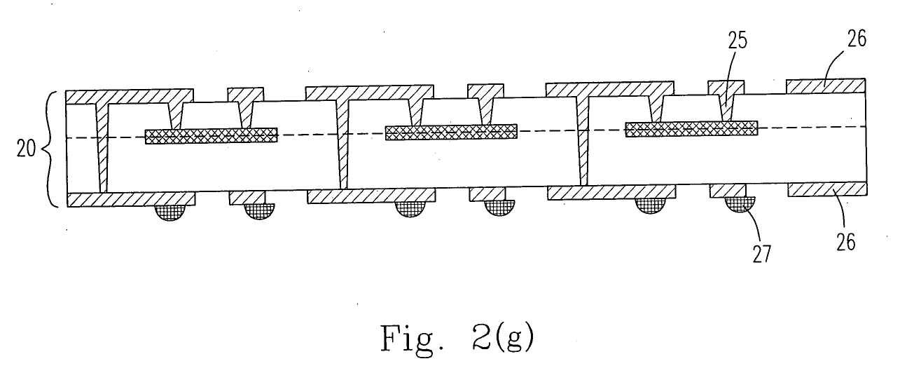

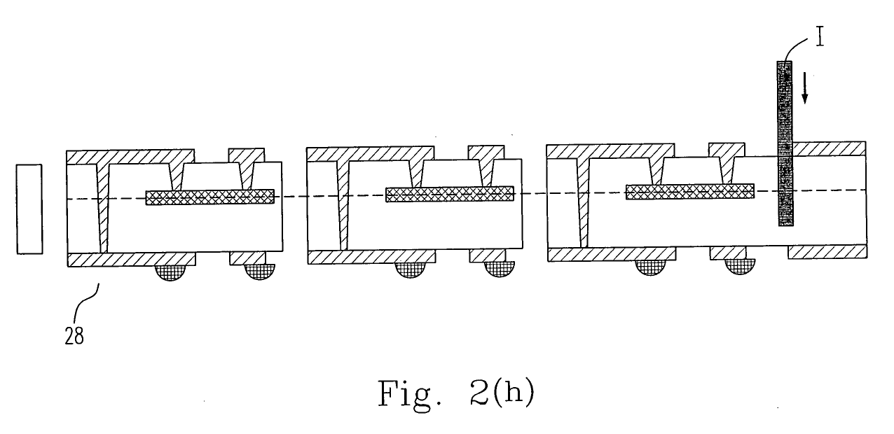

Please refer to FIGS. 2(a) to 2(h), which schematically illustrate the method for fabricating the package structure of the present invention. First, a first substrate 21 is provided as shown in FIG. 2(a). The first substrate 21 is a resin coated copper foil (RCC) substrate, which is made of a copper foil 211 and a resin layer 212 coated thereon. Second, an electronic component 23 is placed on the resin layer 212 of the first substrate 21 as shown in FIG. 2(b). The electronic component 23 is a die and is merely placed on the first substrate 21. The bonding process therefor is needless. Then, the electronic component 23 is covered with a second substrate 22, so that a sandwich structure 20 is formed thereby. The sandwich structure 20 is performed with a lamination process and the electronic component 23 is hence embedded therein as shown in FIG. 2(c). The second substrate 22 is also an RCC substrate, which includes a copper foil 221 and a resin layer 222 coated thereon.

Subsequently, a plurality of vias 24 are fabricated as shown in FIG. 2(d). Each of the UV laser process, the CO₂ laser process and the chemical etching process is typically adopted for providing the plurality of vias 24 running through the second substrate 22 and being achieved to the electronic component 23. However, the UV laser process has more advantages than the others since a fine pitching is able to be achieved thereby. Hence the UV laser process is preferred in this case to fabricate the plurality of vias 24 without damaging the structure therebelow.

After being fabricated, the plurality of vias 24 are filled with a conductive material and a plurality of conductive vias 25 are formed thereby as shown in FIG. 2(e). Then, the copper foil 22 on the sandwich structure 20 with the fabricated conductive vias 25 is patterned, so that a patterning layer 26 is formed. Furthermore, the patterned sandwich structure 20 is wired for having traces thereon as shown in FIG. 2(f).

The package structure of the present invention is basically fabricated through the provided method. For further remaining the pitch for the fabricated package structure, the method also includes a step of performing the ball mounting process thereon, so that a plurality of solder balls 27 are respectively formed on the predetermined positions on the package structure thereby as shown on FIG. 2(g). In order to provide a further protection for the fabricated package structure and the structure thereinside from suffering damages in the sequent processes, the method also includes a step of performing a known solder mask process on the package structure for providing a complete coverage protection thereon.

Finally, the package structure is isolated or singulated as required via the isolation apparatus I, and a single device 28 is hence fabricated as shown in FIG. 2(h).

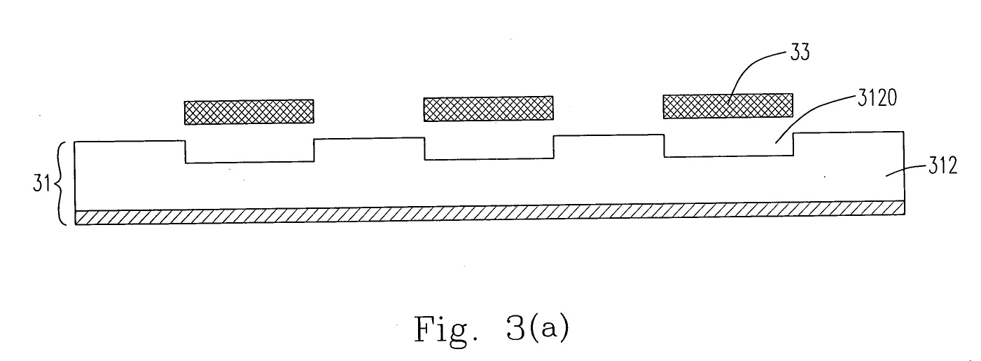

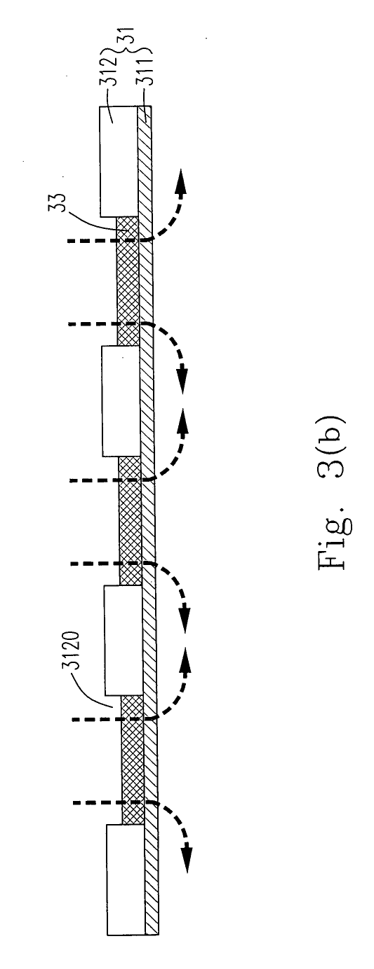

Please refer to FIG. 3(a), which is a diagram illustrating the substrate suitable for the package structure according to a preferred embodiment of the present invention. In order to meet the requirement for miniaturizing the electronic device, the electronic component 33, e.g. a die, in the package structure of the present invention typically has a thickness of 50 μm. Such an electronic component 33 is so thin and miniaturized, and in the fabrication process, it is just directly placed on the RCC substrate 31 but not bonded, e.g. via the conventional wire bonding, the TAB and the FC processes, thereon. Therefore, a plurality of fillisters 3120 are preformed on the resin layer 312 of the RCC substrate 31 and the electronic component 33 is placed into the corresponding fillister 3120 for preventing the electronic component 33 from a perturbation motion.

Moreover, some additives, such as a thermal compound, a super glue, or a gel, are further applied for the adhesion between the electronic component and the copper foil, if the fillister has a depth enough therefor.

Please refer to FIG. 3(b), which is a diagram illustrating another substrate suitable for the package structure according to a preferred embodiment of the present invention. In this case, the depth of the fillister 3120 is deep enough for the electronic component 33 to be directly attached to the copper foil 311 of the RCC substrate 31. Since the copper foil 311 has a great thermal conductivity, the heat produced while the electronic component 33 is in operation is dissipated therethrough as shown by the arrows in FIG. 3(b). Therefore, the electronic device having the package structure of the present invention will exhibit an excellent ability for thermal dissipating.

In addition to the RCC substrate mentioned above, the ABF (Ajinomoto Build-up Film) substrate and the flexible substrate are also suitable for the package structure of the present invention. The flexible substrate is always made of an organic material, such as the polyimide (PI), the polydimethylsiloxane (PDMS), the liquid crystal polymer (LCP) and the polyethylene terephthalate. An electronic device, which is fabricated from such a flexible organic substrate, will exhibit a good flexibility and are able to be applied more extensively.

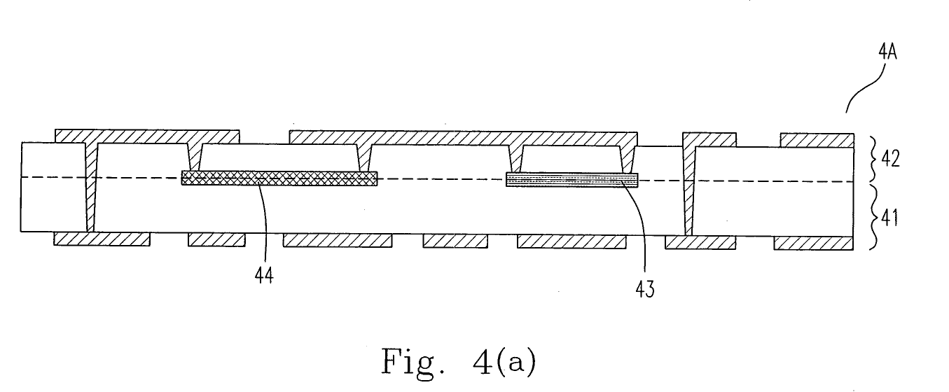

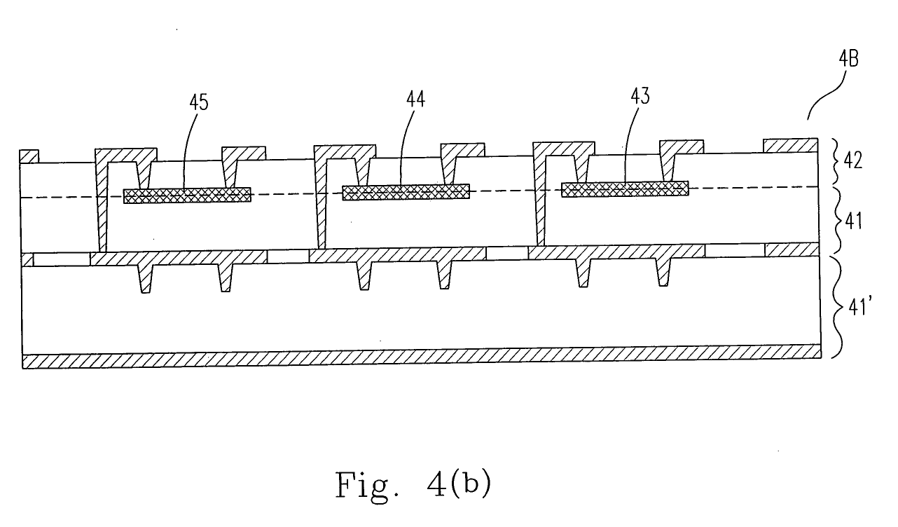

Please refer to FIGS. 4(a) and 4(b), which are diagrams respectively illustrating a 2D package structure 4A and a 3D package structure 4B according to a preferred embodiment of the present invention. After two dies 43 and 44 with different functions are placed between two RCC substrates 41 and 42, the lamination process is performed thereon, so that the 2D package structure 4A is formed as shown in FIG. 4(a). Furthermore, if more dies 43, 44 and 45 with different functions are placed between the RCC substrates 41 and 42, or another RCC substrate 41′ is used and laminated, the 3D package structure 4B is fabricated after the lamination process is performed thereon. Therefore, the method of the present invention is applied for efficiently integrating various dies in a limited space, and accordingly, the package structure with multiple layers and various functions can be fabricated easily.

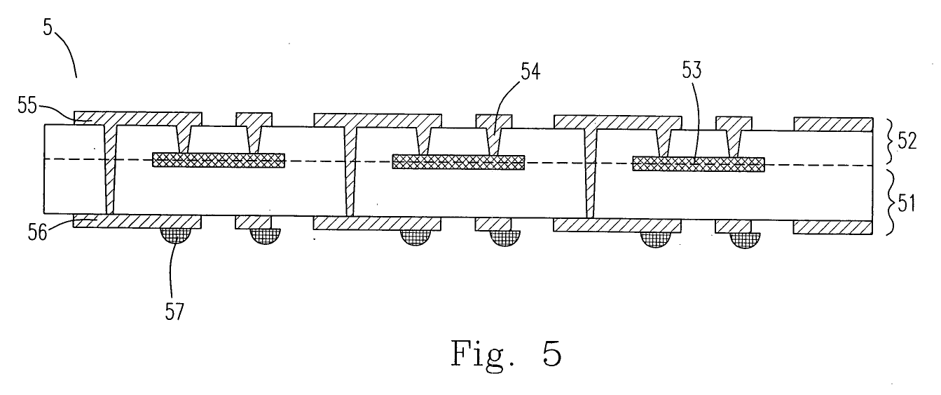

Please refer to FIG. 5, which is a diagram illustrating the package structure according to a second preferred embodiment of the present invention. The package structure 5 has a die 53 between two substrates 51 and 52, and after the lamination process is performed thereon, the die 53 is embedded therein. Plural vias 54 with a conductive material therein are located at the I/O pad of the die 53, and the substrates 51 and 52 are partially penetrated thereby. Hence the respective patterning layers 55 and 56 of the substrates 51 and 52 are connected by the vias 54, and so are the die 53 and the patterning layers 55 and 56 for the signal transmission. The patterning layer 56 further has plural solder balls 57 for keeping the vias 54 with an appropriate pitch.

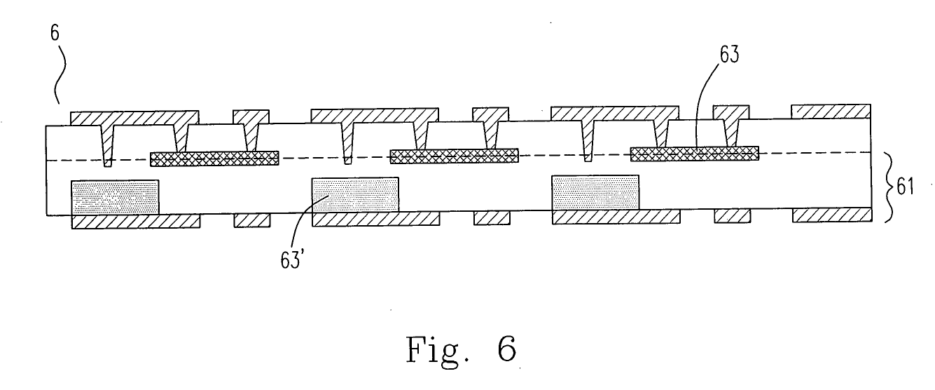

Please refer to FIG. 6, which is a diagram illustrating the package structure according to a third preferred embodiment of the present invention. What is different from the second embodiment is that a known active electronic component or a passive electronic component is also applied in the package structure 6. In addition to the die 63, the typical active electronic component includes a semiconductor, a transistor and an IC. On the other hand, the typical passive electronic component includes a capacitor, a resistor and an inductor which refer to the discrete passive component. Furthermore, a built-in passive component made of a capacitance material, a resistance material or an inductance material is also applied. For example, a resistance material 63′ is first formed on the first substrate 61 by means of the conventional stencil printing process, and is then embedded in the package structure 6 with the die 63 through the method of the present invention.

Compared with the BGA (ball grid array) technique, which has a great value for the electronic package technology, the through hole and the core layer are not needed anymore in the method of the present invention. Therefore, the provided package structure of the present invention is miniaturized due to a smaller PKG (packaging) size. In addition, since the electronic component is embedded between the two substrate by means of the lamination process, the I/O path length of the provided package structure is reduced, so that the electric performance thereof is efficiently improved.

On the other hand, compared with the component built-in module provided by Toshiyuki Asahi, the present invention provides a bumpless package structure with a greater superiority. By the present invention, it is not necessary for the die to use a bump to be connected and further embedded in the package structure or on the patterning layer. Such a bumpless package structure has a miniaturized volume, shorter electrical path, finer line width/space, and the electrical performance thereof is superior since there is no additional interface between the die and the patterning layer in the package structure, and the intensity of the signal is not reduced while being transmitted therethrough.

Based on the above, the present invention provides an improved package structure and an improved fabrication method therefor. The package structure is miniaturized, and has an excellent performance and a great ability for thermal dissipation. Besides, the fabrication is simplified and suitable for various substrates, which are commonly used at present. Therefore, the present invention not only has a novelty and a progressiveness, but also has an industry utility.

While the invention has been described in terms of what is presently considered to be the most practical and preferred embodiment, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An electronic package structure, comprising:
a first substrate having a first upper surface and a first lower surface;
a second substrate having a second upper surface and a second lower surface;
at least an electronic component located between said first lower surface and said second upper surface;
a plurality of vias passing through said second substrate and connected to said electronic component; and
a patterning layer located at least on one of said first upper surface and said second lower surface;
wherein said electronic component is embedded between said first lower surface and said second upper surface by performing a lamination process on said first substrate and said second substrate, and said electronic package structure is patterned and wired via said patterning layer.

2. The electronic package structure according to claim 1, wherein said first substrate is one selected from a group consisting of a resin coated copper-foil substrate, an ajinomoto build-up film substrate and a flexible substrate.

3. The electronic package structure according to claim 1, wherein said second substrate and said first substrate are made of the same material.

4. The electronic package structure according to claim 1, wherein said first substrate further comprises at least a fillister thereon.

5. The electronic package structure according to claim 4, wherein said fillister is pre-formed on said first substrate.

6. The electronic package structure according to claim 5, wherein said electronic component is located on a position corresponding to said fillister.

7. The electronic package structure according to claim 1, wherein said electronic component is one of an active electronic component and a passive electronic component.

8. The electronic package structure according to claim 7, wherein said active component is one selected from a group consisting of a die, a semiconductor, a transistor and an integrated circuit.

9. The electronic package structure according to claim 7, wherein said passive electronic component further comprises one of a discrete passive electronic component and a built-in passive electronic component.

10. The electronic package structure according to claim 9, wherein said discrete passive electronic component is one selected from a group consisting of a capacitor, a resistor and an inductor.

11. The electronic package structure according to claim 9, wherein said built-in passive electronic component is made of one selected from a group consisting of a capacitance material, a resistance material and an inductance material.

12. The electronic package structure according to claim 11, wherein said resistance material is fabricated on said first substrate by a stencil printing process.

13. The electronic package structure according to claim 1, further comprising plural balls on said patterning layer.

14. An electronic package structure, comprising:
a first substrate and a second substrate;
at least a third substrate located between said first substrate and said second substrate;
at least two electronic components respectively located between said first substrate and said third substrate and between said second substrate and said third substrate to form at least a sandwich structure;
a plurality of vias passing through said first substrate and said second substrate, and connected to said electronic components located therebetween; and
a patterning layer located on an outer surface of said sandwich structure;
wherein said electronic components are embedded between said first substrate and said second substrate by performing a lamination process on said sandwich structure.

15. A method for fabricating an electronic package structure comprising steps of:
(a) providing a first substrate;
(b) forming an electronic component on said first substrate;
(c) providing a second substrate on said electronic component, so that said first substrate and said electronic component are covered therewith and a sandwich structure is formed thereby;
(d) performing a lamination process on said sandwich structure, so that said electronic component is embedded therein;
(e) forming a plurality of vias on said sandwich structure;
(f) filling said plurality of vias with a conductive material; and
(g) patterning said sandwich structure.

16. The method according to claim 15, wherein said second substrate is provided on said electronic component by a build-up process in the step (c).

17. The method according to claim 15, wherein said plurality of vias are formed by one selected from a group consisting of a UV laser, a gas laser and a chemical etching in the step (e).

18. The method according to claim 15, after the step (g) further comprising a step of:
(h) performing a solder mask process on said sandwich structure.

19. The method according to claim 15, after the step (g) further comprising a step of:
(h′) performing a ball-mounting process on said sandwich structure.

20. The method according to claim 19, further comprising a step of:
(i) singulating said sandwich structure into said electronic package structure.

21. The method according to claim 15, after the step (g), further comprising a step of:
(h″) singulating said sandwich structure into said electronic package structure.

22. The method according to claim 15, wherein said first substrate is one selected from a group consisting of a resin coated copper-foil substrate, an ajinomoto build-up film substrate and a flexible substrate.

23. The method according to claim 15, wherein said second substrate and said first substrate are made of the same material.

24. The method according to claim 15, wherein said first substrate further comprises at least a fillister thereon.

25. The method according to claim 24, wherein said fillister is pre-formed on said first substrate.

26. The method according to claim 25, wherein said electronic component is located on a position corresponding to said fillister.

27. The method according to claim 15, wherein said electronic component is one of an active electronic component and a passive electronic component.

28. The method according to claim 27, wherein said active component is one selected from a group consisting of a die, a semiconductor, a transistor and an integrated circuit.

29. The method according to claim 27, wherein said passive electronic component further comprises one of a discrete passive electronic component and a built-in passive electronic component.

30. The method according to claim 29, wherein said discrete passive electronic component is one selected from a group consisting of a capacitor, a resistor and an inductor.

31. The method according to claim 29, wherein said built-in passive electronic component is one selected from a group consisting of a capacitance material, a resistance material and an inductance material.

32. The method according to claim 31, wherein said resistance material is fabricated on said first substrate by a printing process.
